(19) United States
(12) Patent Application Publication
(10) Pub. No.: US 2025/0372279 A1
(43) Pub. Date: Dec. 4, 2025

(54) FLEXIBLE CABLE AND ELECTRONIC DEVICE INCLUDING THE SAME

(71) Applicant: Samsung Display Co., LTD., Yongin-si (KR)

(72) Inventor: Min Su JUNG, Yongin-si (KR)

(21) Appl. No.: 19/061,045

(22) Filed: Feb. 24, 2025

(30) Foreign Application Priority Data
Jun. 4, 2024 (KR) 10-2024-0073304

(51) Int. Cl. H01B 7/08; H05K 1/11

(52) U.S. Cl. CPC H01B 7/0861; H05K 1/118; H05K 2201/10356

(57) ABSTRACT

A flexible cable includes: a conductor that includes a first region and a second region disposed opposite to each other along a length direction, and a third region disposed between the first region and the second region; an insulating film that encapsulates the conductor and in which a first connection opening exposing a part of the first region, a second connection opening exposing a part of the second region, and a test opening exposing a part of the third region are defined; and a cover portion that is disposed to be able to be opened and closed on the insulating film to cover the test opening.

This application claims priority to Korean Patent Application No. 10-2024-0073304, filed on Jun. 4, 2024, and all the benefits accruing therefrom under 35 U.S.C. § 119, the content of which in its entirety is herein incorporated by reference.

### BACKGROUND

### 1. Field

The disclosure relates to a flexible cable and an electronic device including the flexible cable.

### 2. Description of the Related Art

In general, in a digital device, all pieces of data are transmitted as electrical signals. In particular, for a high-performance digital device, a system that may effectively transmit relatively large amounts of data between components or devices without information loss is desired.

Recently, as digital devices are being downsized and made lighter, a flexible cable that bends well is being used for an electrical connection between components or devices.

A flexible printed circuit board (“FPCB”), manufactured by laminating copper foil on a flexible insulation substrate, is used to electrically connect two sections with many bends in various electronic devices.

A flexible flat cable (“FFC”), which is less expensive to manufacture than the flexible circuit board, is also used.

### SUMMARY

Embodiments are intended to provide a flexible cable that allows easy confirmation of electrical connectivity, and an electronic device including the flexible cable.

A flexible cable in an embodiment includes: a conductor that includes a first region and a second region disposed opposite to each other along a length direction, and a third region disposed between the first region and the second region; an insulating film that encapsulates the conductor and in which a first connection opening exposing a part of the first region, a second connection opening exposing a part of the second region, and a test opening exposing a part of the third region are defined; and a cover portion that is disposed to be able to be opened and closed on the insulating film to cover the test opening.

In an embodiment, the cover portion may include a fixed portion fixed to the insulating film and a flip portion connected to the fixed portion.

In an embodiment, the cover portion may be an integrated structure.

In an embodiment, the cover portion may be the same material as that of the insulating film.

In an embodiment, the insulating film may include a first outer surface and a second outer surface facing the first outer surface, the test opening may be defined in the first outer surface, and the first connection opening and the second connection opening may be defined in the second outer surface.

In an embodiment, the insulating film may include a first outer surface and a second outer surface opposite to the first outer surface, the test opening and the second connection opening may be defined in the first outer surface, and the first connection opening may be defined in the second outer surface.

In an embodiment, the insulating film may include a first insulating film and a second insulating film bonded to the first insulating film, the test opening may be defined in the first insulating film, and the first connection opening and the second connection opening may be defined in the second insulating film.

In an embodiment, the first connection opening may be exposed from the second insulating film in the first region, and the second connection opening may be exposed from the second insulating film in the second region.

In an embodiment, the first insulating film may include a first end next (adjacent) to the first connection opening and a second end next (adjacent) to the second connection opening, an end of the first region may extend to the first end of the first insulating film, and an end of the second region may extend to the second end of the first insulating film.

In an embodiment, the end of the first region may be exposed from the second insulating film, and the end of the second region may be exposed from the second insulating film.

In an embodiment, the insulating film may include a first insulating film and a second insulating film bonded to the first insulating film, the test opening and the second connection opening may be defined in the first insulating film, and the first connection opening may be defined in the second insulating film.

In an embodiment, the first connection opening may be exposed from the second insulating film in the first region, and the second connection opening may be exposed from the first insulating film in the second region.

In an embodiment, the second insulating film may include a first end next (adjacent) to the first connection opening and a second end next (adjacent) to the second connection opening, and an end of the second region may extend to the second end of the second insulating film.

In an embodiment, the end of the second region may be exposed from the first insulating film.

In an embodiment, the flexible cable may further include a support portion separated from the cover portion on the insulating film.

In an embodiment, the cover portion and the support portion may be disposed on the same surface of the insulating film.

In an embodiment, the cover portion and the support portion may be disposed on different surfaces of the insulating film.

By the embodiments, the electrical connectivity of the flexible cable may be readily verified.

### BRIEF DESCRIPTION OF THE DRAWINGS

The above and other embodiments, advantages and features of this disclosure will become more apparent by describing in further detail embodiments thereof with reference to the accompanying drawings.

FIG. 1 is a schematic perspective view of a flexible cable.

FIG. 2 is a schematic perspective view of the flexible cable of FIG. 1.

FIG. 3 is a bottom view of the flexible cable of FIG. 1.

FIG. 4 is a cross-sectional view of FIG. 1, taken along line IV-IV′.

FIG. 5 is a perspective view that illustrates the cover portion of the flexible cable of FIG. 1 in a closed state.

FIG. 6 is a schematic top-plan view of the flexible cable of FIG. 5.

FIG. 7 is a cross-sectional view of FIG. 5, taken along line VII-VII′.

FIG. 8 is a perspective view of a flexible cable.

FIG. 9 is a bottom view of the flexible cable of FIG. 8.

FIG. 10 is a cross-sectional view of FIG. 8, taken along line X-X′.

FIG. 11 is a perspective view of a flexible cable.

FIG. 12 is a bottom view of the flexible cable of FIG. 11.

FIG. 13 is a cross-sectional view of FIG. 11, taken along line XIII-XIII′.

FIG. 14 is a perspective view of a flexible cable.

FIG. 15 is a bottom view of the flexible cable of FIG. 14.

FIG. 16 is a cross-sectional view of FIG. 14, taken along line XVI-XVI′.

FIG. 17 is a block diagram illustrating an electronic device according to an embodiment.

FIG. 18 is a view illustrating an embodiment of the electronic device of FIG. 17 implemented as a smartphone.

### DETAILED DESCRIPTION

Hereinafter, regarding the accompanying drawings, various embodiments of the disclosure will be described in detail such that those of ordinary skill in the art may easily carry out the disclosure. The disclosure may be implemented in several different forms and is not limited to the embodiments described herein.

To clearly describe the disclosure, parts irrelevant to the description have been omitted, and like reference numerals designate like elements throughout the specification.

In the drawings, the size and thickness of each element are arbitrarily illustrated for convenience of description, and the disclosure is not necessarily limited to as illustrated in the drawing. In the drawings, the thickness of layers, films, panels, regions, etc., are exaggerated for clarity. In addition, in the drawings, the thickness of some layers and regions is exaggerated for better understanding and ease of description.

It will be understood that when an element such as a layer, film, region, or substrate is also referred to as being “on” another element, it may be directly on the other element or intervening elements may also be present. In contrast, when an element is also referred to as being “directly on” another element, there are no intervening elements present. Further, throughout the specification, the word “on” a target element will be understood to mean disposed above or below the target element, and will not necessarily be understood to mean disposed “at an upper side” based on an opposite to gravity direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “in a plan view” means viewing a target portion from the top, and the phrase “in a cross-section” means viewing a cross-section formed by vertically cutting a target portion from the side.

In this specification, x, y, and z represent the directions of coordinate axes that intersect each other perpendicularly. The plane formed by the x and y-axes is referred to as the xy plane, the plane formed by the y and z-axes is referred to as the yz plane, and the plane formed by the z and x-axes is referred to as the zx plane.

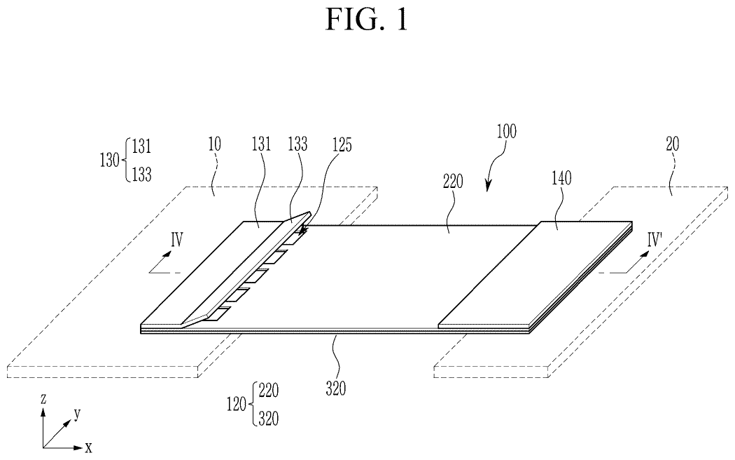

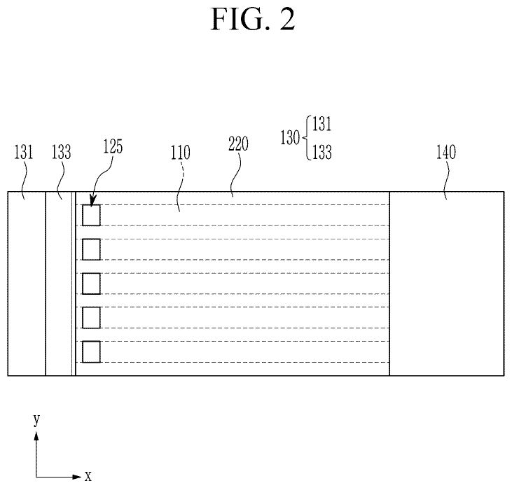

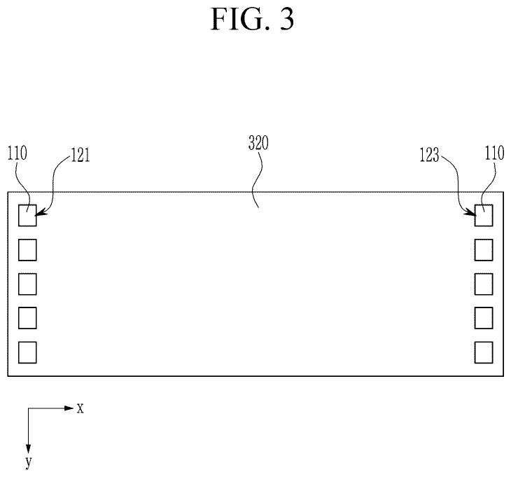

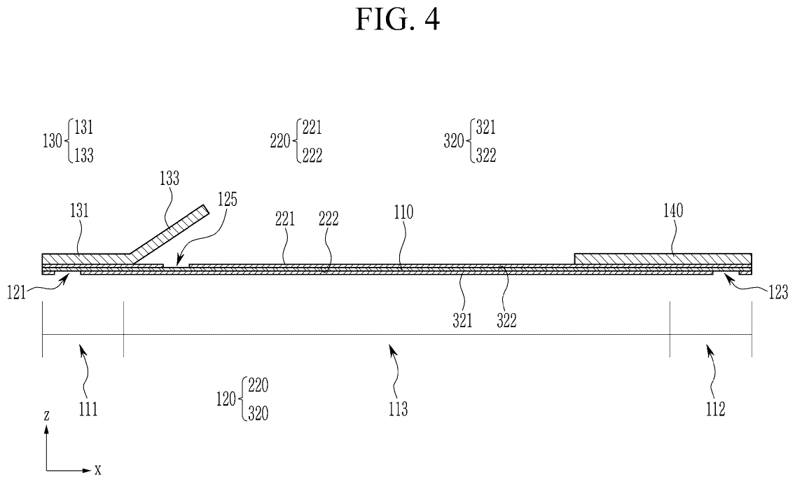

FIG. 1 is a schematic perspective view of a flexible cable in an embodiment, FIG. 2 is a schematic perspective view of the flexible cable of FIG. 1, FIG. 3 is a bottom view of the flexible cable of FIG. 1, and FIG. 4 is a cross-sectional view of FIG. 1, taken along line IV-IV′.

Referring to FIG. 1, FIG. 2, FIG. 3, and FIG. 4, a flexible cable 100 in an embodiment may electrically connect electronic parts or electronic devices.

In an embodiment, the flexible cable 100 may electrically connect a display panel 10 and a main board 20, for example. The display panel 10 is for displaying an image and may be a liquid crystal display panel, an organic light-emitting display panel, or the like, but the illustrated embodiment is not limited thereto. The main board 20 may be a printed circuit board including an integrated circuit chip or the like.

The flexible cable 100 includes a conductor 110, an insulating film 120, and a cover portion 130.

The conductor 110 includes or consists of a conductive material (e.g., copper (Cu) or aluminum (Al)) capable of transmitting an electrical signal.

The conductor 110 may include a plurality of conductors spaced apart from each other along a width direction (y-axis direction) of the flexible cable 100 or may have a complex circuit structure. The flexible cable 100 may be a flexible flat cable (“FFC”) or a flexible circuit board (“FPCB”).

The conductor 110 includes a first region 111, a second region 112, and a third region 113.

The first region 111 and the second region 112 are opposite to each other along a length direction (x-axis direction) of the conductor 110. In an embodiment, the first region 111 may be one end in the length direction (x direction) of the conductor 110, and the second region 112 may be the end in the opposite length direction (x direction) of the conductor 110, for example.

The third region 113 is a region between the first region 111 and the second region 112.

The insulating film 120 encapsulates the conductor 110, and a first connection opening 121, a second connection opening 123, and a test opening 125 are defined in the insulating film 120.

The insulating film 120 is provided to insulate and protect the conductor 110 and may include or consist of polyethylene terephthalate (“PET”), polyethylene (“PE”), urethane, or silicon material. However, the illustrated embodiment is not limited to this, and the type of material that may insulate the conductor 110 is not particularly limited.

The insulating film 120 may include a first insulating film 220 and a second insulating film 320. The first insulating film 220 and the second insulating film 320 may be bonded to each other while disposing the conductor 110 therebetween.

The first insulating film 220 includes a first surface 221 and a second surface 222 which face each other in a thickness direction (z-axis direction). The first surface 221 corresponds to the outer surface of the first insulating film 220, and the second surface 222 corresponds to the inner surface of the first insulating film 220. That is, the first surface 221 is a surface that does not contact the conductor 110, and the second surface 222 is a surface that contacts the conductor 110.

The second insulating film 320 includes a third surface 321 and a fourth surface 322 which are opposite to each other in the thickness direction (z-axis direction). The third surface 321 corresponds to the outer surface of the second insulating film 320, and the fourth surface 322 corresponds to the inner surface of the second insulating film 320. That is, the third surface 321 is a surface that does not contact conductor 110, and the fourth surface 322 is a surface that contacts conductor 110.

The first connection opening 121 exposes a part of the first region 111 of the conductor 110.

The first connection opening 121 is defined in a side of the second insulating film 320 with the conductor 110 as a reference. That is, the first connection opening 121 is a region from which a part of the second insulating film 320 corresponding to the first region 111 of the conductor 110 is removed. A portion of the first region 111 of the conductor 110 is exposed through the first connection opening 121. The flexible cable 100 may be electrically connected to another component or device through a conductive material connected to the first connection opening 121.

The second connection opening 123 exposes a part of the second region 112 of the conductor 110.

The second connection opening 123 is defined in an opposite side of the second insulating film 320 with conductor 110 as a reference. That is, the second connection opening 123 is a region from which a part of the second insulating film 320 corresponding to the second region 112 of the conductor 110 is removed. A portion of the second region 112 of the conductor 110 is exposed through the second connection opening 123. The flexible cable 100 may be electrically connected to another component or device through a conductive material connected to the second connection opening 123.

The test opening 125 exposes a part of the third region 113 of the conductor 110.

The test opening 125 is defined in the first insulating film 220 sides with the conductor 110 as a reference. That is, the test opening 125 is a region from which a part of the first insulating film 220 corresponding to the third region 113 of the conductor 110 is removed. A part of the third region 113 of the conductor 110 is exposed through the test opening 125.

Test opening 125 may be used to identify the position where a fault occurs in the electrical connection of the flexible cable 100.

When checking whether the electrical connectivity of the flexible cable 100 is good, the electrical connectivity may be checked by connecting an input signal line to the first connection opening 121 and an output signal line to the second connection opening 123. In an alternative embodiment, the electrical connectivity may be verified by connecting the output signal line to the first connection opening 121 and the input signal line to the second connection opening 123. In either case, when signal transmission between the first connection opening 121 and the second connection opening 123 is not properly performed, the electrical connectivity of the flexible cable 100 may be determined to be poor. However, in this case, it is difficult to determine whether the defect occurred on a side in which the first connection opening 121 is defined or a side in which the second connection opening 123 is defined.

In the illustrated embodiment, the electrical connectivity may be confirmed by connecting the input signal line (or output signal line) to the first connection opening 121 and connecting the output signal line (or input signal line) to the test opening 125. In addition, the electrical connectivity may be verified by connecting the output signal line (or input signal line) to the second connection opening 123 and the input signal line (or output signal line) to the test opening 125. That is, in the illustrated embodiment, the electrical connectivity on a side in which the first connection opening 121 is defined may be separately checked, and the electrical connectivity on a side in which the second connection opening 123 is defined may be separately checked. According to this, it may be confirmed whether or that an electrical connection failure occurred in the first connection opening 121 and/or the second connection opening 123.

The cover portion 130 is openable and closable on the first insulating film 220 to cover the test opening 125.

The cover portion 130 may include or consist of the same material as that of the insulating film 120. In an embodiment, the cover portion 130 may be polyethylene terephthalate (“PET”), polyethylene (“PE”), urethane, or silicon material, for example.

The cover portion 130 includes a fixed portion 131 and a flip portion 133.

The fixed portion 131 is fixed to the first surface 221 of the first insulating film 220. In an embodiment, the fixed portion 131 may be bonded to an end side in the length direction (x-axis direction) of the first insulating film 220.

The flip portion 133 is connected to the fixed portion 131. One side of the flip portion 133 is connected to the fixed portion 131 and an opposite side is a free end. Therefore, the flip portion 133 may contact the first surface 221 of the first insulating film 220 or be spaced apart from the first surface 221 of the first insulating film 220. When the flip portion 133 contacts the first surface 221 of the first insulating film 220, the flip portion 133 may cover the test opening 125. When the flip portion 133 is spaced from the first surface 221 of the first insulating film 220, the flip portion 133 may expose the test opening 125.

The cover portion 130 may have an integrated structure. That is, the fixed portion 131 and the flip portion 133 may be formed as one piece. However, the illustrated embodiment is not limited to this, and the fixed portion 131 and the flip portion 133 may be combined to form the cover portion 130.

Since the cover portion 130 has a structure as above, the test opening 125 may be opened and closed. Therefore, when the electrical connectivity of the flexible cable 100 needs to be verified, the cover portion 130 may be opened to expose the test opening 125.

The cover portion 130 may also serve to prevent damage to the flexible cable 100. That is, since the fixed portion 131 of the cover portion 130 is fixed to the first surface 221 at the end side of the length direction (x-axis direction) of the first insulating film 220, the strength of the flexible cable 100 of the fixed portion may be reinforced.

As a result, when the flexible cable 100 is connected to another component or electronic device, the end of the flexible cable 100 in the length direction (x-axis direction) may not be easily broken or damaged.

The flexible cable 100 may further include a support portion 140. The support portion 140 may be placed on the first insulating film 220 at an opposite position to the cover portion 130 in the length direction (x-axis direction).

Like the cover portion 130, the support portion 140 may serve to prevent damage to the flexible cable 100.

The support portion 140 may have the same structure as that of the cover portion 130. That is, the support portion 140 may have a structure including a portion fixed to the first insulating film 220 and a remaining portion that is not fixed. In this case, the support portion 140 has a structure that may contact the first surface 221 of the first insulating film 220 or be separated from the first surface 221.

In another embodiment, the shape of the support portion 140 corresponds to the cover portion 130, but unlike the cover portion 130, the entirety of the support portion 140 may be fixed to the first surface 221 of the first insulating film 220. In this case, the support portion 140 does not include a component corresponding to the flip portion 133 of the cover portion 130.

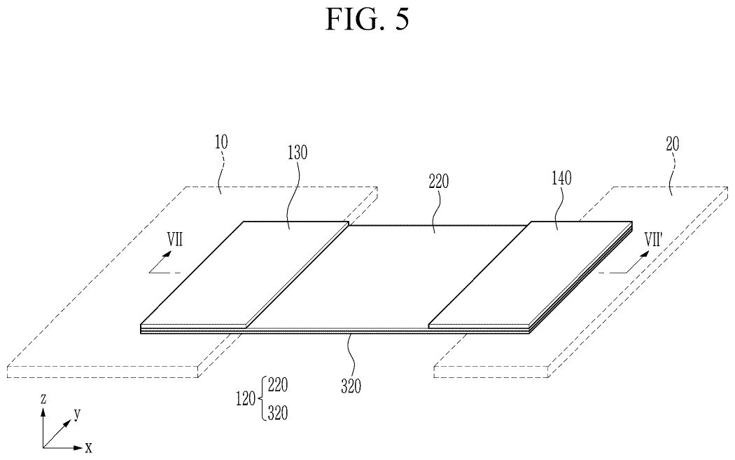

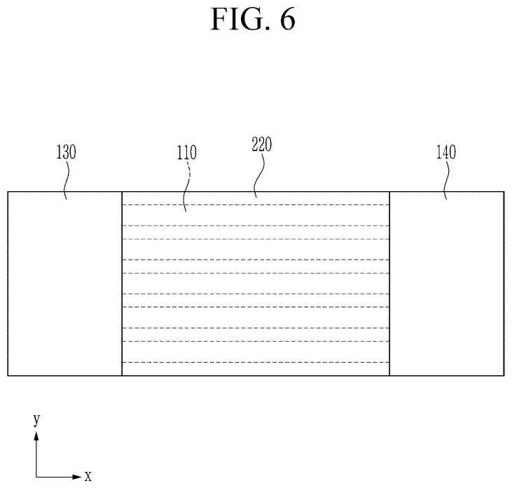

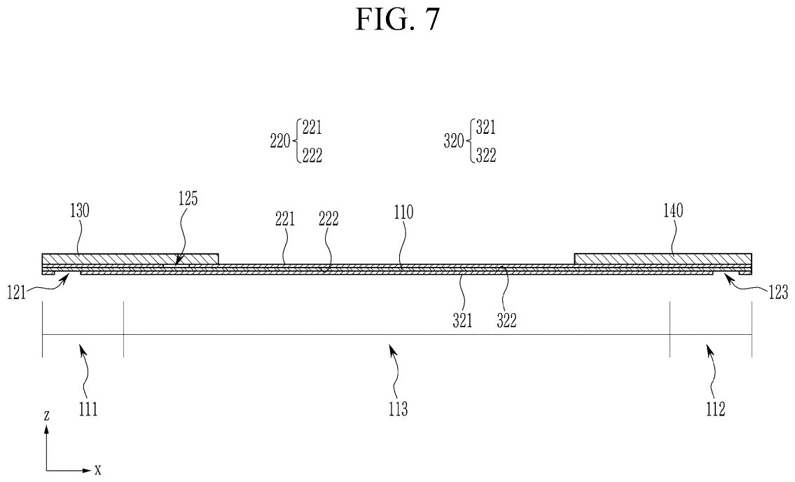

FIG. 5 is a perspective view that illustrates the cover portion of the flexible cable of FIG. 1 in a closed state, FIG. 6 is a schematic top plan view of the flexible cable of FIG. 5, and FIG. 7 is a cross-sectional view of FIG. 5, taken along line VII-VII′.

Referring to FIG. 5, FIG. 6, and FIG. 7, the cover portion 130 covers the test opening 125 while being in a state of contacting the first surface 221 of the first insulating film 220. In this state, since the test opening 125 is not exposed to the outside, the conductor 110 may be protected from foreign substances or the like.

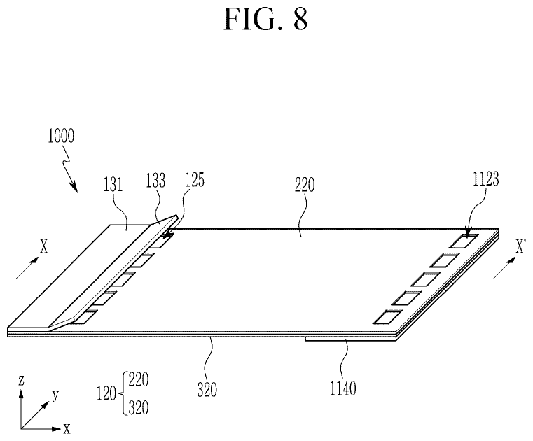

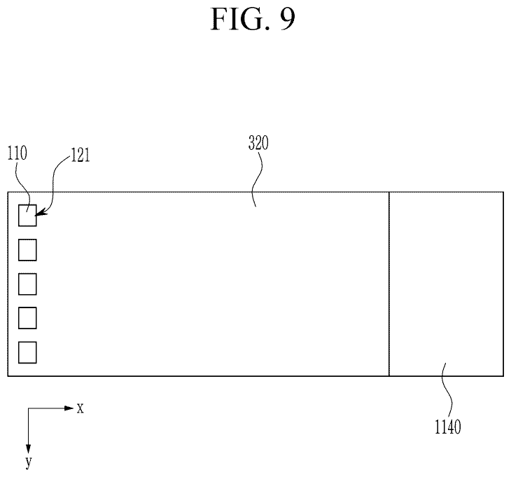

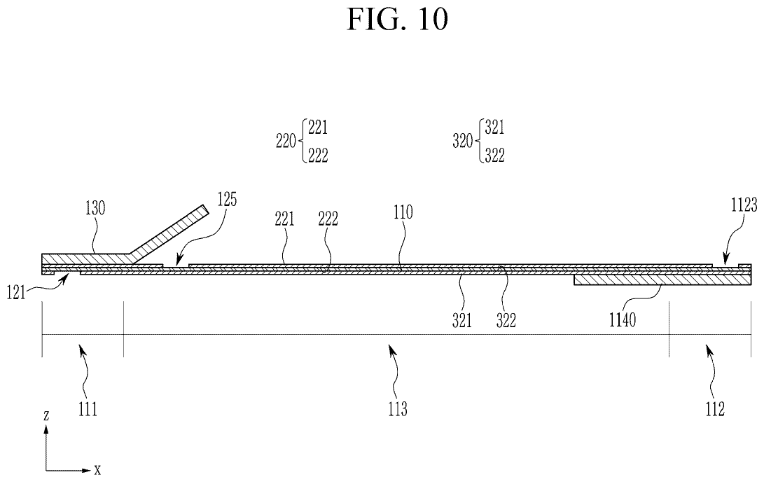

FIG. 8 is a perspective view of a flexible cable in another embodiment, FIG. 9 is a bottom view of the flexible cable of FIG. 8, and FIG. 10 is a cross-sectional view of FIG. 8, taken along line X-X′.

Referring to FIG. 8, FIG. 9, and FIG. 10, components, except for a second connection opening 1123 and a support portion 1140 of a flexible cable 1000, are identical to those of the flexible cable of FIG. 1, and therefore duplicate descriptions will be omitted.

The second connection opening 1123 exposes a part of a second region 112 of a conductor 110.

The second connection opening 1123 is defined in a side of a first insulating film 220 with the conductor 110 as a reference. That is, the second connection opening 1123 is a region from which a part of the first insulating film 220 corresponding to the second region 112 of the conductor 110 is removed. A portion of the second region 112 of the conductor 110 is exposed through the second connection opening 1123. The flexible cable 1000 may be electrically connected to another component or device through a conductive material connected to the second connection opening 1123.

The support portion 1140 may be disposed on a second insulating film 320 at a position opposing the second connection opening 1123 in a thickness direction (z-axis direction). The support portion 1140 may have the same structure as a cover portion 130, and unlike the cover portion 130, the entirety of the support portion 1140 may be fixed to a third surface 321 of the second insulating film 320.

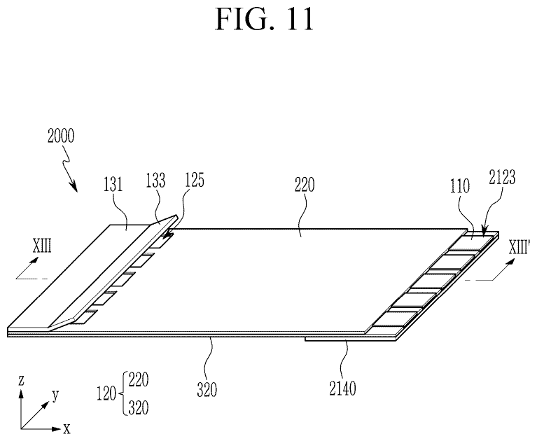

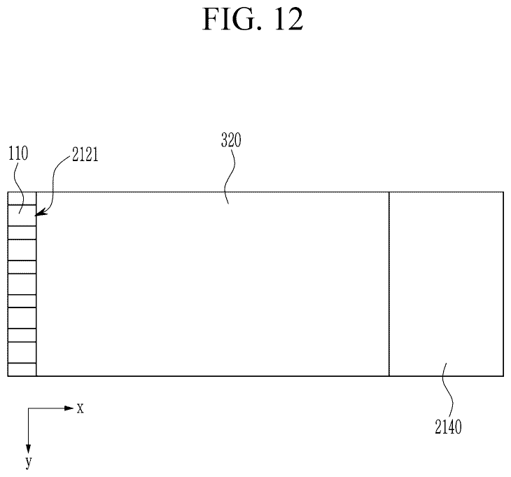

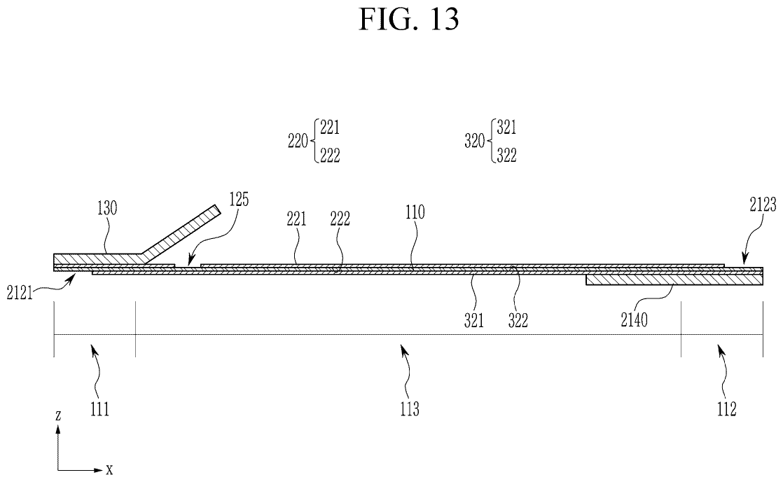

FIG. 11 is a perspective view of another embodiment of a flexible cable, FIG. 12 is a bottom view of the flexible cable of FIG. 11, and FIG. 13 is a cross-sectional view of FIG. 11, taken along line XIII-XIII′.

Referring to FIG. 11, FIG. 12, and FIG. 13, components, except for a first connection opening 2121, a second connection opening 2123, and a support portion 2140 of a flexible cable 2000, are identical to those of the flexible cable of FIG. 1, and therefore duplicate descriptions will be omitted.

The first connection opening 2121 exposes a part of a first region 111 of a conductor 110.

The first connection opening 2121 is defined in a side of a second insulating film 320 with the conductor 110 as a reference. That is, the first connection opening 2121 is a region from which a part of the second insulating film 320 corresponding to the first region 111 of the conductor 110 is removed. Here, in a region extending from a length directional (x-axis direction) end of the first insulating film 220 to a predetermined point inside the first insulating film 220, the second insulating film 320 on the conductor 110 is completely removed. That is, the first connection opening 2121 exposes a region including the end of the first region 111 in the length direction (x-axis direction) of the conductor 110. The flexible cable 2000 may be electrically connected to another component or device through a conductive material connected to the first connection opening 2121.

The second connection opening 2123 is defined in an opposite side of the first insulating film 220 with the conductor 110 as a reference. That is, the second connection opening 2123 is a region from which a part of the first insulating film 220 corresponding to the second region 112 of the conductor 110 is removed. Here, in a region extending from the length directional (x-axis direction) end of the second insulating film 320 to a predetermined point inside the second insulating film 320, the first insulating film 220 on the conductor 110 is completely removed. That is, the second connection opening 2123 exposes a region including the end of the second region 112 in the length direction (x-axis direction) of the conductor 110. The flexible cable 2000 may be electrically connected to another component or device through a conductive material connected to the second connection opening 2123.

The support portion 2140 may be placed on the second insulating film 320 at a position facing the second connection opening 2123 in the thickness direction (z-axis direction). A support portion 2140 may have the same structure as a cover portion 130, or, unlike the cover portion 130, the entirety of the support portion 2140 may be fixed to a third surface 321 of the second insulating film 320.

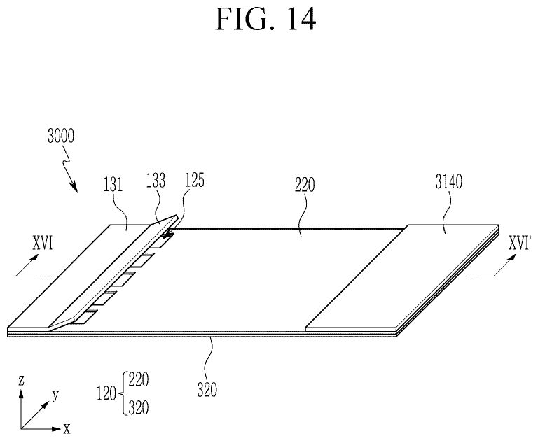

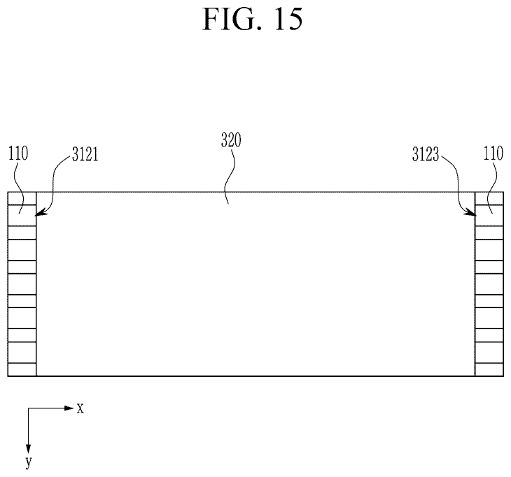

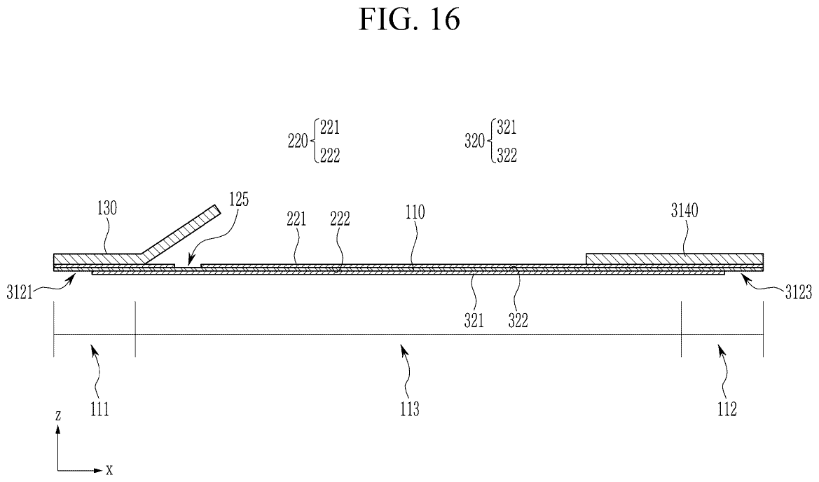

FIG. 14 is a perspective view of another embodiment of a flexible cable, FIG. 15 is a bottom view of the flexible cable of FIG. 14, and FIG. 16 is a cross-sectional view of FIG. 14, taken along line XVI-XVI′.

Referring to FIG. 14, FIG. 15, and FIG. 16, components, except for a second connection opening 3123 and a support portion 3140 of a flexible cable 3000, are identical to those of the flexible cable of FIG. 11, and therefore duplicate descriptions will be omitted.

A first connection opening 3121 exposes a part of the first region 111 of the conductor 110, and the second connection opening 3123 exposes a part of the second region 112 of the conductor 110. The first connection opening 3121 is defined in a side of a second insulating film 320, and the second connection opening 3123 is defined in an opposite side of the second insulating film 320 with a conductor 110 as a reference. That is, the second connection opening 3123 is a region from which a part of the second insulating film 320 corresponding to a second region 112 of the conductor 110 is removed. Here, in a region extending from a length directional (x-axis direction) end of a first insulating film 220 to a predetermined point inside the first insulating film 220, the second insulating film 320 on the conductor 110 is completely removed. That is, the second connection opening 3123 exposes a region including the end of the second region 112 in the length direction (x-axis direction) of the conductor 110. The flexible cable 3000 may be electrically connected to another component or device through a conductive material connected to the second connection opening 3123.

The support portion 3140 may be placed on the first insulating film 220 at a position facing the second connection opening 3123 in the thickness direction (z-axis direction). The support portion 3140 may have the same structure as that of the cover portion 130, or, unlike the cover portion 130, the entirety of the support portion 3140 may be fixed to the first surface 221 of the first insulating film 220.

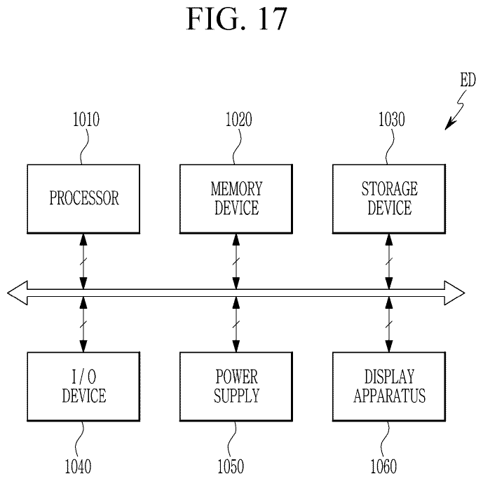

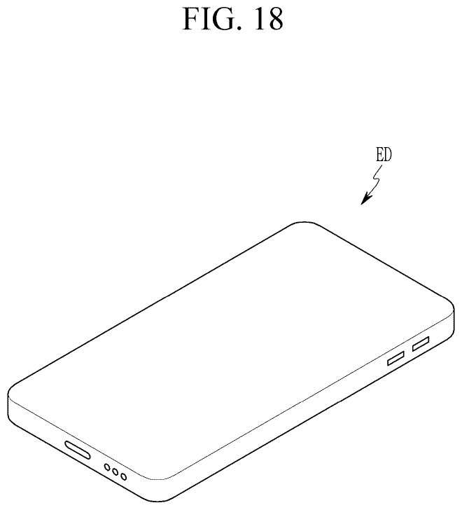

FIG. 17 is a block diagram illustrating an electronic device according to an embodiment. FIG. 18 is a view illustrating an embodiment of the electronic device of FIG. 17 implemented as a smartphone.

Referring to FIGS. 17 and 18, in an embodiment, an electronic device ED may include a processor 1010, a memory device 1020, a storage device 1030, an input/output (“I/O”) device 1040, a power supply 1050, and a display device 1060. The display device 1060 may include the display panel 10 and the main board 20 and the flexible cable 100 electrically connecting the display panel 10 and the main board 20 in FIG. 1. The electronic device ED may further include a plurality of ports for communicating with a video card, a sound card, a memory card, a universal serial bus (“USB”) device, or the like. In an embodiment, the electronic device ED may be implemented as a television. In another embodiment, the electronic device ED may be implemented as a smart phone. However, embodiments are not limited thereto, in another embodiment, the electronic device ED may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device ED. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device ED. The power supply 1050 may provide power to the display device 1060. The display device 1060 may be coupled to other components via the buses or other communication links. In an embodiment, the display device 1060 may be included in the I/O device 1040.

In an embodiment the electronic device may be implemented as a smartphone. However the embodiments of the present disclosure may be exemplary and may not be limited to this. For example, the electronic device ED may be implemented as a mobile phone, a video phone, a smart pad, a smart watch, a television, a tablet PC, a vehicle display, a computer monitor, a notebook computer, a head-mounted display device, etc. In addition, the electronic device ED may be a television, a monitor, a notebook computer, or a tablet. In addition, the electronic device ED may be a car.

While this disclosure has been described in connection with what is presently considered to be practical embodiments, it is to be understood that the disclosure is not limited to the disclosed embodiments. On the contrary, it is intended to cover various modifications and equivalent arrangements included within the spirit and scope of the appended claims.

What is claimed is:

1. A flexible cable comprising:
a conductor which includes:
a first region and a second region opposite to each other along a length direction; and
a third region between the first region and the second region;
an insulating film which encapsulates the conductor and in which a first connection opening exposing a part of the first region, a second connection opening exposing a part of the second region, and a test opening exposing a part of the third region are defined; and
a cover portion which is openable and closable on the insulating film and covers the test opening.

2. The flexible cable of claim 1, wherein:
the cover portion comprises a fixed portion fixed to the insulating film and a flip portion connected to the fixed portion.

3. The flexible cable of claim 2, wherein:
the cover portion is an integrated structure.

4. The flexible cable of claim 1, wherein:
the cover portion is a same material as a material of the insulating film.

5. The flexible cable of claim 1, wherein:
the insulating film comprises a first outer surface and a second outer surface facing the first outer surface,
the test opening is defined in the first outer surface, and
the first connection opening and the second connection opening are defined in the second outer surface.

6. The flexible cable of claim 1, wherein:
the insulating film includes a first outer surface and a second outer surface opposite to the first outer surface,
the test opening and the second connection opening are defined in the first outer surface, and
the first connection opening is defined in the second outer surface.

7. The flexible cable of claim 1, wherein:
the insulating film includes a first insulating film and a second insulating film bonded to the first insulating film,
the test opening is defined in the first insulating film, and
the first connection opening and the second connection opening are defined in the second insulating film.

8. The flexible cable of claim 7, wherein:
the first connection opening is exposed from the second insulating film in the first region, and
the second connection opening is exposed from the second insulating film in the second region.

9. The flexible cable of claim 8, wherein:
the first insulating film includes a first end next to the first connection opening and a second end next to the second connection opening,
an end of the first region extends to the first end of the first insulating film, and
an end of the second region extends to the second end of the first insulating film.

10. The flexible cable of claim 9, wherein:
the end of the first region is exposed from the second insulating film, and
the end of the second region is exposed from the second insulating film.

11. The flexible cable of claim 1, wherein:
the insulating film includes a first insulating film and a second insulating film bonded to the first insulating film,
the test opening and the second connection opening are defined in the first insulating film, and
the first connection opening is defined in the second insulating film.

12. The flexible cable of claim 11, wherein:
the first connection opening is exposed from the second insulating film in the first region, and
the second connection opening is exposed from the first insulating film in the second region.

13. The flexible cable of claim 12, wherein:
the second insulating film includes a first end next to the first connection opening and a second end next to the second connection opening, and
an end of the second region extends to the second end of the second insulating film.

14. The flexible cable of claim 13, wherein:
the end of the second region is exposed from the first insulating film.

15. The flexible cable of claim 1, further comprising a support portion separated from the cover portion on the insulating film.

16. The flexible cable of claim 15, wherein:
the cover portion and the support portion are disposed on a same surface of the insulating film.

17. The flexible cable of claim 15, wherein:
the cover portion and the support portion are disposed on different surfaces of the insulating film.

18. An electronic device comprising:
a display panel;
a main board; and
a flexible cable which electrically connects the display panel and the main board, the flexible cable comprising:
a conductor which includes:
a first region and a second region opposite to each other along a length direction; and
a third region between the first region and the second region;
an insulating film which encapsulates the conductor and in which a first connection opening exposing a part of the first region, a second connection opening exposing a part of the second region, and a test opening exposing a part of the third region are defined; and
a cover portion which is openable and closable on the insulating film and covers the test opening.

19. The electronic device of claim 18, wherein:
the cover portion comprises a fixed portion fixed to the insulating film and a flip portion connected to the fixed portion.

20. The electronic device of claim 19, wherein:
the cover portion is an integrated structure.
